(19) United States
(12) Patent Application Publication
(10) Pub. No.: US 2009/0009212 A1
(43) Pub. Date: Jan. 8, 2009

(54) Calibration system and method

(76) Inventor: Martin Brox, Munich (DE)

Correspondence Address: QIMONDA NORTH AMERICA CORP., 3000 CENTREGREEN WAY, CARY, NC, 27513, US

(21) Appl. No.: 11/824,668

(22) Filed: Jul. 2, 2007

(51) Int. Cl. H03K 17/16; H03K 19/0175

(52) U.S. Cl. 326/30; 326/82

(57) ABSTRACT

A system and method to calibrate an output driver impedance of an output driver based on a termination device of a controller.

### BACKGROUND

High-speed systems operation at very high frequencies employ dedicated calibration devices and methods to deal with signal reflections or interferences. Signal reflection causes noise, which lowers signal quality. In a high-speed data transfer system, high-quality signals are required.

Therefore, there is a need for improved calibration systems and methods.

### BRIEF DESCRIPTION OF THE DRAWINGS

The accompanying drawings are included to provide a further understanding of the invention, and are incorporated in and constitute a part of this specification. The drawings illustrate embodiments of the present invention and together with the description serve to explain the principles of the invention. Other embodiments of the present invention will be readily appreciated as they become better understood by reference to the following detailed description. Like reference numerals designate corresponding parts.

FIG. 1 shows a memory system according to one embodiment of the present invention;

FIG. 2 shows the interconnection between a controller and a memory module according to one embodiment of the present invention;

FIG. 3 shows a calibration sequence in accordance with an embodiment of the present invention;

FIG. 4 shows a data system according to one embodiment of the present invention; and

FIG. 5 shows an operational sequence of a calibration method according to one embodiment of the present invention.

Advantages and details of the present invention will become apparent to the reader of the present invention when reading the detailed description referring to preferred embodiments of the present invention.

Throughout the detailed description and the accompanying drawings same or similar components, units or devices will be referenced by same reference numerals for clarity purposes.

### DETAILED DESCRIPTION

System calibration is often necessary for a system to meet specified operating conditions. For example, in a system employing a memory device, calibration of output drivers and termination resistors may be provided by means of external impedances (resistors) which are mounted on a printed circuit board PCB of the memory system or computer system, for instance.

Additionally a dedicated external impedance to calibrate the controller is provided. That is, two different impedances are used, the first one to calibrate the (memory) controller and the second one to calibrate the output drivers of the memory system. In addition, the two calibration sequences can operate independently from each other. Therefore, the controller calibration is provided independently from the memory calibration.

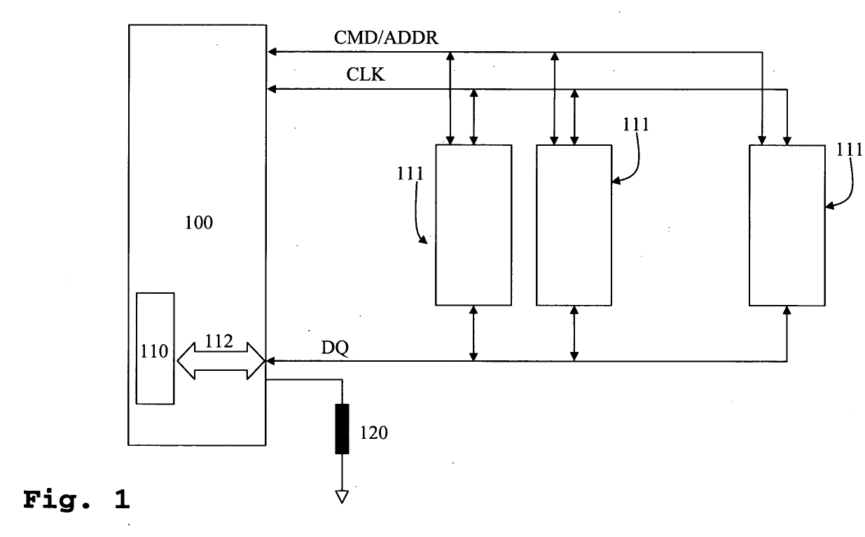

A memory system according to one embodiment of the present invention is shown in FIG. 1. The memory system may be employed as a plurality of integrated circuits or devices. According to one embodiment a plurality of memory modules or devices 111 are controlled by a memory controller 100. The memory controller 100 corresponds to logic circuitry controlling operation of each connected memory device 111. The memory controller 100 may be in turn controlled by a central processing unit, for instance, which is not shown with reference to FIG. 1.

The memory controller 100 employs a plurality of input/output terminals. For the sake of simplicity only the relevant ones are shown. The memory controller 100 includes a command and address path CMD/ADDR interconnecting each of the memory devices 111. According to one embodiment the memory devices 111 are dynamic random access modules (DRAM). The system may include any type of memory device, or any logic device. Additionally a clock signal path CLK is provided. The clock signal CLK is used to synchronize the data input/output to and out from each of the memory devices 111. The command path CMD may be used to convey commands like read or write to each memory device 111. Each memory device can be additionally equipped with a logic device or a controller, respectively. Information transfer is accomplished over a bi-directional data bus, referenced as DQ.

The memory controller 100 according to one embodiment of the present invention provides an on die termination device (ODT) 110, which is to be used to calibrate the memory system of FIG. 1. Additionally, an external impedance 120 is provided which is in turn used to calibrate the ODT of the memory controller 100.

According to one embodiment of the invention the data bus DQ is used to convey calibration signals or information. That is, the data bus may be quiet during calibration, because of data interferences with other signals like data signals during usual operation of the data bus DQ for instance. The output drivers, namely the off-chip drivers of the memory devices 111 are calibrated or adjusted respectively based on the ODT 110 of the memory controller 100. The term off-chip means that the signals are driven out of the device. Each signal line of the data bus DQ is connected by means of an off-chip driver circuit of the corresponding memory modules 111 to the memory device. The signal mismatch of the pull-up and pull-down components of the output drivers may be reduced by calibrating the memory devices 111.

According to one embodiment the off-chip drivers of each memory device 111 includes a corresponding PMOS and NMOS leg (not shown). The corresponding legs are adapted to provide the pull-up and pull-down currents for driving the output signal of the memory system. By adjusting the pull-up and pull-down drive strength of the above-mentioned output drivers the output levels and the rise and fall times of the output signal can be optimized. The adjustment is provided by the calibration operation operated within each memory device 111. Therefore, an optimized impedance setting for each of the PMOS and NMOS legs is provided.

During the calibration operation the memory controller 100 calibrates itself against the external impedance 120. That is, the ODT 110 is now calibrated with reference to the external impedance 120. The impedance 120 shows a dedicated value, which may be set by a memory system manufacturer for instance. Subsequently, the memory devices 111 use the already calibrated ODT 110 as a basis for calibration. It should be noted that other external impedances 120 may be used.

For instance, the external impedance 120 can be embedded within the controller 100, but other architectures are feasible. The reference number 112 symbolizes the local connection between the ODT 110 and an I/O terminal (not shown in FIG. 1) of the controller. The I/O terminal is used to connect the external impedance 120 and the data bus DQ used to convey the calibration signals to the memory devices 111, according to one embodiment of the present invention. The I/O terminal can include a plurality of connectors to connect the data bus DQ and/or the external impedance 120.

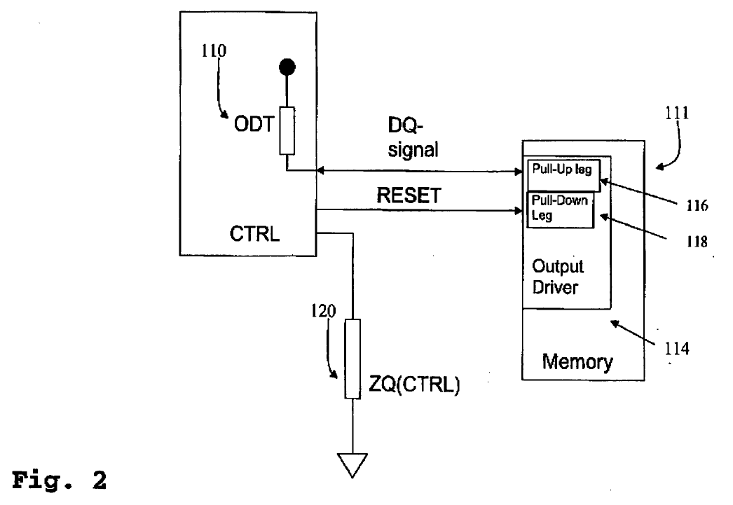

With reference to FIG. 2, shows another embodiment of the invention.

On a system-level according to one embodiment shown in FIG. 2, the calibration resistor of the memory is omitted. Thereby, calibration of the memory device 111 is performed based on the on-die termination (ODT) 110 of the controller CTRL over one DQ-signal line for instance.

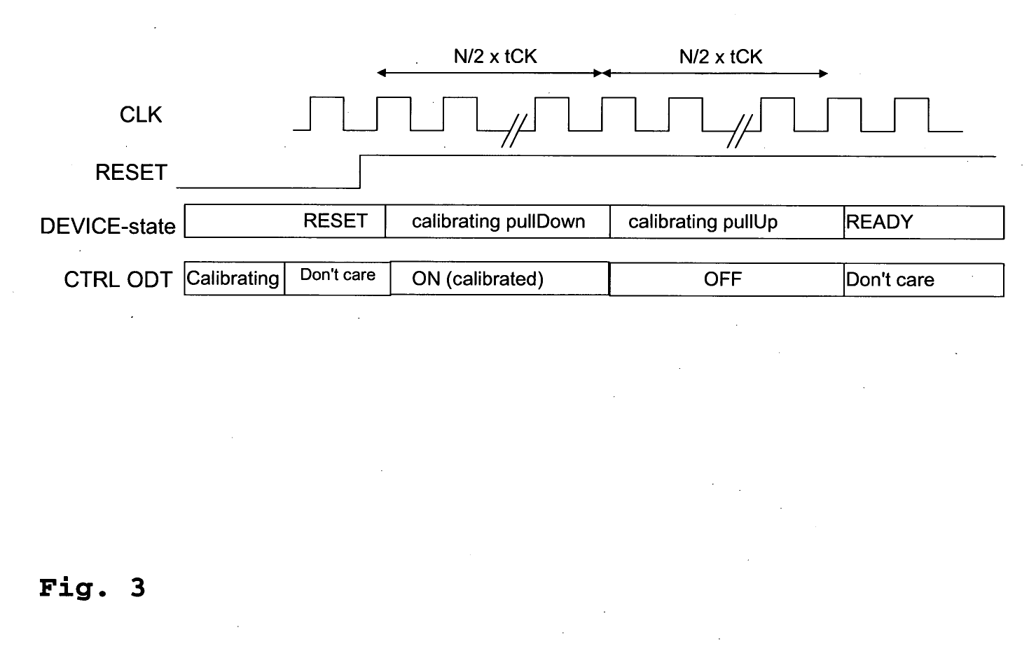

An embodiment of the calibration operation is shown with reference to FIG. 3.

The controller calibrates itself on the basis of impedance 120 while holding the memory device 111 in a RESET mode. The RESET mode of the memory device 111 may be controlled by a reset line RESET, which is schematically shown in FIG. 2.

The controller 100 activates the ODT 110 against e.g. high-level. The ODT-impedance 110 is calibrated on the basis of the impedance 120. The external impedance 120 may be implemented on the PCB of the system, for instance. Other implementations like, on package integration of the external impedance or similar are possible as well.

The RESET signal over the reset line is activated or released, which triggers the calibration operation of the memory device 111. According to this example the ODT 110 is calibrated against a high-level voltage (as described above), the memory device 111 calibration includes calibration of the pull-down leg against the controller-ODT 110. The pull-down leg is a functional part of the output driver of the memory device 111.

After a number of clock cycles, for example N/2 cycles of the system clock (not shown), the calibration of the pull-down leg is finished and the controller 100 switches off the ODT 120 such that the memory device 111 can calibrate the pull-up leg against its own (and already calibrated) pull-down leg. Thereby achieving a consistent calibration because only one external impedance 120 for calibration is necessary. The reference sign N corresponds to the number of clock cycles of the system clock, for instance.

Both the controller 100 and the memory 111 are configured to count the number of clock-cycles expired such that switching-off of controllers ODT 110 and switching-on of the calibration-mode of the memory 111 can be easily synchronized.

Thus, after N cycles, the calibration is finished. Consequently, external calibration resistors or impedances for the memory device 111 are not required and the calibration results of the memory device 111 and controller 100 are matched, because only one external resistor 120 has to be used in this embodiment. Further no copy of the output driver circuits for calibration on the memory device is required. That is, the calibration operation may be configured to use the usual output drivers of the integrated device.

FIG. 3 shows a calibration operation of an integrated circuit according to an embodiment of the present invention. According to FIG. 3 two signals are shown: the system clock signal CLK and the reset signal RESET. The clock signal may be generated by a clock generator, or the like. The reset signal may be driven by the controller 100 or by the CPU 420. The illustrations at the bottom of the figure represent the mode of operation of the memory 111 and of the controller 100, respectively.

During operation of the memory system the memory controller 100 may generate a reset signal RESET, which is conveyed to a memory device 111. Accordingly the memory device is switched into a calibration mode or state. Once the reset signal RESET is received the memory and/or the controller will count the clock cycles. The duration of one clock cycle is referenced as tCK according to FIG. 3. The calibration of the ODT device 110 of the controller 100 may be performed during the calibrating period illustrated at the bottom of FIG. 3, CTRL ODT.

According to one embodiment the reset signal corresponds to a calibration start signal, that is the calibration start signal or reset signal indicates that a calibration mode is to be entered.

The calibration of the pull-down leg can be N/2 clock cycles from a reset. The calibration of the pull-down leg is performed on the basis of the ODT 110 of the controller 100. The ODT 110 of the controller is activated during N/2 time cycles. The ODT 110 may be switched off and the calibration of the pull-up leg of the driver is done based on the already calibrated pull-down leg.

According to one embodiment of the invention, the calibration of the pull-up leg takes N/2 clock cycles as well but other clock counts are possible. The CTRL ODT at the bottom of FIG. 3 representing the current state of the ODT 110 of the controller 100 shows a “don't care” (no operation needed) interval during the status of the ODT 110 is not relevant.

After N cycles the memory device 111 is ready to be addressed and the calibration operation is completed. According to other embodiments of the calibration operation, the pull-down leg can be calibrated on the basis of the pull-up leg. That is, the calibration operation can be mirrored but other implementations are possible and will be within the skill of one of ordinary skill in the art.

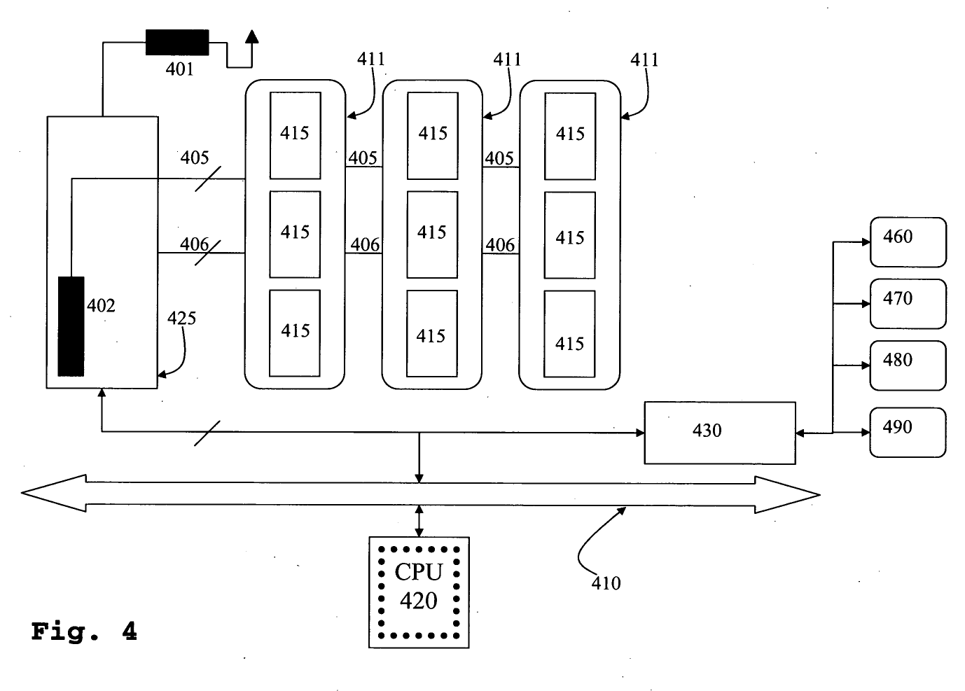

FIG. 4 shows a data system in accordance with one embodiment of the present invention. The data system may be a part of a computer system or the like. The system according to one embodiment includes a memory controller 425 which is connected by means of a command bus 406 and a data bus 405 to a plurality of memory modules 411. Each of the memory modules 411 includes a plurality of memory devices or circuits [. 415. According to an example each memory module 411 includes three memory circuits 415, but other architectures are possible. For instance each memory 415 could be stacked into one chip package corresponding to a stacked technology. However, the memory controller is configured to address each memory circuit via the command bus 406 and the data bus 405. The data bus 405 is configured to transfer the data stored within the memory modules or circuits, respectively. The data bus 405 may include a plurality of lines configured to transport, among other signals, calibration signals and/or commands. Additionally the memory controller 425 generates a clock signal, which is transmitted to each memory module 411 and memory circuit 415.

In the following the calibration signals are conveyed by the data bus or DQ-bus 405. It should be understood that the same calibration operation could also be carried out by the command/address bus 406, for instance. According to one embodiment the calibration signals are transmitted via a calibration pattern. The general clock signal provided by the memory controller 425 may be used to control the calibration signal pattern or the calibration signal sequence.

According to one embodiment the memory controller 425 may perform the calibration operation during the initialization of the memory subsystem after power-up for instance. In another embodiment, calibration may be performed periodically or after leaving a sleep state of the system.

The memory controller includes an on die termination device ODT 402 can be used as a reference during the calibration of the memory circuits 415. The ODT 402 is calibrated with reference to an external device 401. The external device 401 may be a resistor for instance, and it could be implemented on the PCB. It is possible that the external device can be omitted and an integrated resistor is used. However, according to one possible embodiment the ODT 402 is calibrated on the basis of an external resistor 401.

During calibration of the memory circuits 415 it is assumed that the ODT 402 is already calibrated. The memory circuits receive a RESET signal for instance in a calibration mode, which is shown with reference to FIG. 3. The RESET signal can be conveyed via the DQ bus 405 or in an alternative embodiment via the address bus 406. Also other implementations are possible.

According to one embodiment the DQ bus 405 may be used to transmit the calibration signals. During the calibration operation the memory circuit 415 calibrates its pull-up leg based on the already calibrated ODT 402 and the pull-down leg is in turn calibrated based on the already calibrated pull-up leg. An analogous calibration scenario could be achieved if the pull-down leg is calibrated first.

The system according to one embodiment of the present invention may be controlled by the CPU. The CPU 420 communicates with the other components by means of a system bus 410.

Additionally, the data system includes an extension bus 430 with an extension bus controller (not shown). The extension bus 430 communicates with a plurality of peripheral devices 460, 470, 480, 490, like for instance a keyboard, a hard disk, an I/O interface and a user I/O interface. Additional peripheral multimedia adapters or the like are also feasible.

Although the data system of FIG. 4 is shown having three memory circuits 415, it should be noted that a plurality of memory circuits 415 can be used. Analogously, a plurality of memory modules 411 and external devices 401 could also be implemented.

Embodiments of the present invention may be used for devices employing graphic memory systems like GDDR-Systems or the like. But also mobile devices, computer systems or the like may be equipped with a memory system according to embodiments of the present invention.

The memory device 111 according to embodiments of the invention may be any data storing semiconductor device, e.g., a PLA, PAL, or ROM device, for instance a PROM, EPROM, EEPROM, or flash memory device, etc., or e.g. a RAM device, for instance an SRAM or DRAM, e.g., a DDR-DRAM or DDR2-DRAM (DDR DRAM=Double Data Rate DRAM), etc. wherein calibration of drivers, for instance, is desired. Further the memory device 111 may comprise one single integrated circuit chip, e.g., one single memory, microprocessor, or microcontroller chip, etc. mounted into one single chip package, for instance. Alternatively, several integrated circuit chips may be mounted into one single chip package, e.g. two, three, or four chips, etc.

For instance, the chip package may comprise two or four DRAM chips, with one chip stacked upon the other, which correspond to a “stacked DRAM”.

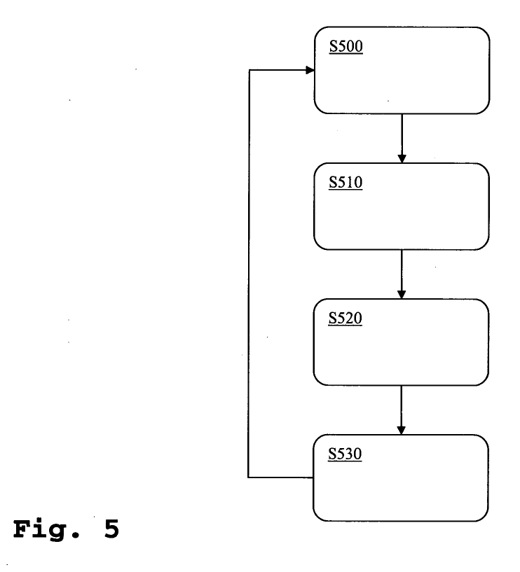

FIG. 5 shows calibration operation of a calibration method according to one embodiment of the present invention. The operation can be implemented within a memory circuit, like a DRAM for instance but is not limited to a DRAM and could be the devices noted above.

In a first step S500 a DRAM or other circuitry may receive a reset signal from a controller indicating that a calibration operation is to be performed. According to the operational step S510 the output driver impedance of the circuitry is calibrated on the basis of an on die termination of the memory controller.

According to a step S520 a calibration pattern received by the circuitry is executed and the operation may come to an end S530. The operation may be restarted by means of a RESET signal, and thus a second iteration can be carried out.

Although the invention is described above with reference to embodiments according to the accompanying drawings, it is clear that the invention is not restricted thereto but can be modified in several ways within the scope of the appended claims.

What is claimed is:

1. An apparatus, comprising:
a device having an output driver;
a controller coupled to the device, the controller comprising a termination device;
wherein an output driver impedance of the output driver is calibrated on the basis of the termination device of the controller.

2. The apparatus according to claim 1, wherein the device is a memory device.

3. The apparatus according to claim 1, wherein the device is a memory module comprising at least one memory device.

4. The apparatus according to claim 1, wherein the termination device is an on die termination device with controllable impedance.

5. The apparatus according to claim 1, wherein the controller is coupled to the device by a bus.

6. The apparatus according to claim 1, wherein the controller supplies a reset signal to the device.

7. The apparatus according to claim 6, wherein the reset signal is transmitted by a bus.

8. A method, comprising:
receiving, at a device, a signal from a controller to start a calibration operation of an output driver of the device;
calibrating the output driver impedance based on a termination device of the controller.

9. The method according to claim 8, further comprising:
executing a calibration signal pattern indicating a calibration operation.

10. The method according to claim 8, further comprising:
calibrating a pull-up leg of the output driver based on the termination device of the controller.

11. The method according to claim 8, further comprising:
calibrating a pull-down leg of the output driver based on the termination device of the controller.

12. The method according to claim 11, further comprising:
calibrating a pull-up leg of the output driver based on the calibrated pull-down leg of the output driver.

13. The method according to claim 8, wherein the calibration is performed periodically.

14. The method of claim 8, wherein the calibration is performed after a sleep state of the device.

15. A system, comprising:
a central processing unit to control the system;
at least one device with corresponding output drivers;
a controller to control operation of the at least one device;
wherein a impedance of the output drivers is calibrated on the basis of a termination device of the controller.

16. The system according to claim 15, wherein the termination device is an on die termination device with controllable impedance.

17. The system according to claim 15, wherein the controller is coupled to the device by a bus.

18. The system according to claim 15, wherein the controller controls the device via a reset signal.

19. The system according to claim 15, wherein the device is a memory module comprising at least one memory device.

20. The system according to claim 19, wherein the memory device is a dynamic random access memory.

21. The system according to claim 15, wherein the reset signal is transmitted over a bus.

22. A system, comprising:
a controller having a termination device with a controllable impedance;
at least one device connected to the controller;
at least one external calibration impedance to calibrate the termination device of the controller;
wherein an output driver of the device is calibrated on the basis of the termination device of the controller.

23. The system according to claim 21, wherein the controller is connected to the at least one device by a bus.

24. The system according to claim 21, wherein the device is a memory module.

25. The system according to claim 21, further comprising a central processing unit to control the operation of the system.
